(19) United States
(12) Patent Application Publication
(10) Pub. No.: US 2018/0228016 A1
(43) Pub. Date: Aug. 9, 2018

(54) WIRE-BOND CAGE IN CONFORMAL SHIELDING

(71) Applicant: QUALCOMM Incorporated, San Diego, CA (US)

(72) Inventors: Daeik Daniel KIM, Del Mar, CA (US); Jie FU, San Diego, CA (US); Manuel ALDRETE, Encinitas, CA (US); Babak NEJATI, San Diego, CA (US); Husnu Ahmet MASARACIOGLU, Del Mar, CA (US)

(21) Appl. No.: 15/429,144

(22) Filed: Feb. 9, 2017

(51) Int. Cl. H05K 1/02; H05K 3/30; H05K 1/11; H05K 13/00; H05K 3/40

(52) U.S. Cl. CPC H05K 1/023; H05K 3/30; H05K 3/4038; H05K 13/0023; H05K 1/115

(57) ABSTRACT

In a package such as a radio frequency (RF) module, an external shield may be provided to shield the package from external influences as well as to shield the devices within the package from undesirable affecting devices outside of the package. The package may also include an internal shield to suppress adverse effects of the signal generated by an aggressor device within the external shield to other devices within the external shield.

### FIELD OF DISCLOSURE

The field of the disclosed subject matter generally relates to shielding a package such as in semiconductor devices and modules. In particular, the field of the disclosed subject matter relates to shielding a package so as to provide both external and internal isolation of signals.

### BACKGROUND

FIG. 1 illustrates an example of a conventional radio frequency (RF) module 100 that receives and transmits wireless signals through an antenna 165. The RF module 100 includes a power amplifier (PA) 120, a duplexer (DUP) 135 and a low noise amplifier (LNA) 155 all contained within a conformal shield 110. For transmission, the PA 120 generates outgoing signals, which are routed to the antenna 165 through the DUP 135. Thick arrows (indicating high power) show the path of the outgoing signals from the PA 120 to the antenna 165. For reception, the antenna 165 receives the incoming signals, which are routed to the LNA 155 through the DUP 135. Thin arrows (indicating low power) show the path of the incoming signals from the antenna 165 to the LNA 155.

Since both the outgoing and the incoming signals are present in the RF module 100, it is possible that one can contaminate the other. However, because the outgoing signal is much stronger than the incoming signal, the effect on the outgoing signal due to the incoming signal is minimal On the other hand, the effect on the incoming signal due to the outgoing signal can be very significant. As a result, the contamination of the incoming signal is of significant concern.

In the context of the RF module 100, it is then desirable to prevent the PA 120 generated high power outgoing signals from reaching the LNA 155. In FIG. 1, the DUP 135 performs this function by isolating the high power outgoing signals from the low power incoming signals so that the two signals not interfere with each other. Through proper isolation, the low power incoming signals can be routed to the LNA 155.

As indicated, the PA 120, the DUP 135 and the LNA 155 are within the conformal shield 110. Since the RF module 100 handles both high and low power signals, users typically require that the RF module 100 be shielded from external influences, and such shielding is normally provided by the conformal shield 110. The conformal shield 110 prevents the devices within the conformal shield 110—e.g., the PA 120, the DUP 135 and the LNA 155—from being contaminated by external signals. The conformal shield 110 also prevents the devices within the conformal shield 110 from undesirably affecting devices outside of the conformal shield 110.

As indicated, the DUP 135 isolates the incoming and the outgoing signals from each other. Unfortunately, even if the DUP 135 performs its isolation function well, the incoming signals can still be contaminated by the PA 120. This is because high power outgoing signal generated by the PA 120 can actually travel on the conformal shield 110. In effect, the PA 120 acts as an aggressor to couple the high power outgoing signal to the conformal shield 110, and thereby disturb the whole RF module 100. In particular, a top layer of the conformal shield 110 essentially becomes an antenna for the PA 120 aggression. Recall that the conformal shield 110 is the grounded. When the PA 120 injects the high power outgoing signal to the conformal shield 110, noise is increased to the LNA 155. The noise can be described as “shaking” the ground, and the LNA 155 must operate against such shaking the ground.

### SUMMARY

This summary identifies features of some example aspects, and is not an exclusive or exhaustive description of the disclosed subject matter. Whether features or aspects are included in, or omitted from this Summary is not intended as indicative of relative importance of such features. Additional features and aspects are described, and will become apparent to persons skilled in the art upon reading the following detailed description and viewing the drawings that form a part thereof.

An exemplary package is disclosed. The package may comprise a substrate with first and second surfaces, a ground plane on the second surface of the substrate, and an external shield on the first surface of the substrate. The external shield may comprise one or more side shields and a top shield. The side shields may be electrically coupled to the ground plane such that the top shield is electrically coupled to the ground plane through the side shields. The package may also comprise a plurality of devices on the first surface of the substrate and within the external shield. The plurality of devices may include an aggressor device. The package may further comprise a wire bond cage on the first surface of the substrate and within external shield. The wire bond cage may define an interior shielding area within which at least a part of the aggressor device is contained. A height of the wire bond cage may be above the aggressor device. The wire bond cage may be electrically coupled to the ground plane such that there is at least one path from the wire bond cage to the ground plane other than through the external shield.

An exemplary method of manufacturing a package is disclosed. The method may comprise forming a substrate with first and second surfaces, forming a ground plane on the second surface of the substrate, and forming an external shield on the first surface of the substrate. The external shield may comprise one or more side shields and a top shield. The side shields may be electrically coupled to the ground plane such that the top shield is electrically coupled to the ground plane through the side shields. The method may also cforming a plurality of devices, including an aggressor device, on the first surface of the substrate and within the external shield. The method may further comprise forming a wire bond cage on the first surface of the substrate and within external shield such that the wire bond cage defines an interior shielding area within which at least a part of the aggressor device is contained, and such that a height of the wire bond cage is above the aggressor device. Forming the wire bond cage may comprise electrically coupling the wire bond cage to the ground plane such that there is at least one path from the wire bond cage to the ground plane other than through the external shield.

An exemplary package is disclosed. The package may comprise a substrate with first and second surfaces, a ground plane on the second surface of the substrate, and means for external shielding on the first surface of the substrate. The means for external shielding may comprise means for side shielding and means for top shielding. The means for side shielding may be electrically coupled to the ground plane such that the means for top shielding is electrically coupled to the ground plane through the means for side shielding. The package may also comprise a plurality of devices on the first surface of the substrate and within the means for external shielding. The plurality of devices may include an aggressor device. The package may further comprise means for internal shielding on the first surface of the substrate and within the means for external shielding. The means for internal shielding may define an interior shielding area within which at least a part of the aggressor device is contained. A height of the means for internal shielding may be above the aggressor device. The means for internal shielding may be electrically coupled to the ground plane in which there is at least one path from the means for internal shielding to the ground plane other than through the means for external shielding.

### BRIEF DESCRIPTION OF THE DRAWINGS

The accompanying drawings are presented to aid in the description of examples of one or more aspects of the disclosed subject matter and are provided solely for illustration of the examples and not limitation thereof.

FIG. 1 illustrates a conventional radio frequency module;

FIG. 2 illustrates an example of a radio frequency module according to a non-limiting aspect;

FIGS. 3A and 3B illustrate side and top views of an example package according to a non-limiting aspect;

FIGS. 3C and 3D illustrate perspective views of the example package illustrated in FIGS. 3A and 3B;

FIG. 4 illustrates a flow chart of an example method of manufacturing a package according to a non-limiting aspect;

FIG. 5 illustrates examples of devices with a package integrated therein.

### DETAILED DESCRIPTION

Aspects of the subject matter are provided in the following description and related drawings directed to specific examples of the disclosed subject matter. Alternates may be devised without departing from the scope of the disclosed subject matter. Additionally, well-known elements will not be described in detail or will be omitted so as not to obscure the relevant details.

The word “exemplary” is used herein to mean “serving as an example, instance, or illustration.” Any embodiment described herein as “exemplary” is not necessarily to be construed as preferred or advantageous over other embodiments. Likewise, the term “embodiments” does not require that all embodiments of the disclosed subject matter include the discussed feature, advantage or mode of operation.

The terminology used herein is for the purpose of describing particular examples only and is not intended to be limiting. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, processes, operations, elements, and/or components, but do not preclude the presence or addition of one or more other features, integers, processes, operations, elements, components, and/or groups thereof.

Further, many examples are described in terms of sequences of actions to be performed by, for example, elements of a computing device. It will be recognized that various actions described herein can be performed by specific circuits (e.g., application specific integrated circuits (ASICs)), by program instructions being executed by one or more processors, or by a combination of both. Additionally, these sequence of actions described herein can be considered to be embodied entirely within any form of computer readable storage medium having stored therein a corresponding set of computer instructions that upon execution would cause an associated processor to perform the functionality described herein. Thus, the various aspects may be embodied in a number of different forms, all of which have been contemplated to be within the scope of the claimed subject matter. In addition, for each of the examples described herein, the corresponding form of any such examples may be described herein as, for example, “logic configured to” perform the described action.

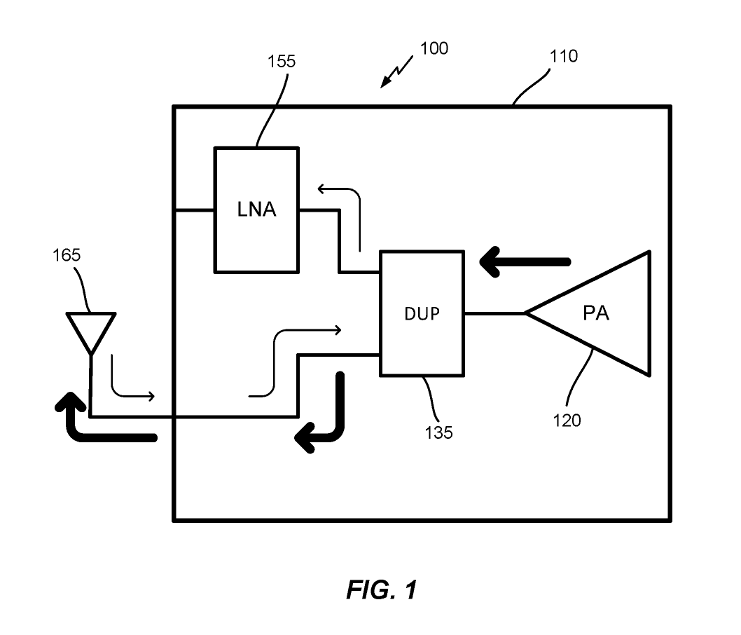

Recall that the conventional RF module 100 of FIG. 1 handles both the outgoing and incoming signals. Also recall that contamination of the weak incoming signal due to the strong outgoing signal is of significant concern. In this respect, since the PA 120 is the source of the contaminating signal, the PA 120 may be viewed as an “aggressor device”. To maintain sensitivity to the incoming signal, the conventional RF module 100 includes the DUP 135 which isolates the two signals from each other so that the received incoming signal is directed to the LNA 155 with minimal interference.

But as indicated, even if the DUP 135 performs its isolation function well, the incoming signal can still be contaminated. This is because at least some form of the PA 120 generated high power outgoing signal can travel on the conformal shield 110 which acts as an antenna for the PA 120 aggression. For example, the RF outgoing signal waves can induce current on the conformal shield 110, and the DUP 135 cannot mitigate such induced signals traveling on the conformal shield 110. When this occurs, the noise to the LNA 155 is increased since the LNA 155 has to operate against the “shaking” the ground. This in turn reduces the LNA's 135 sensitivity to the incoming signal.

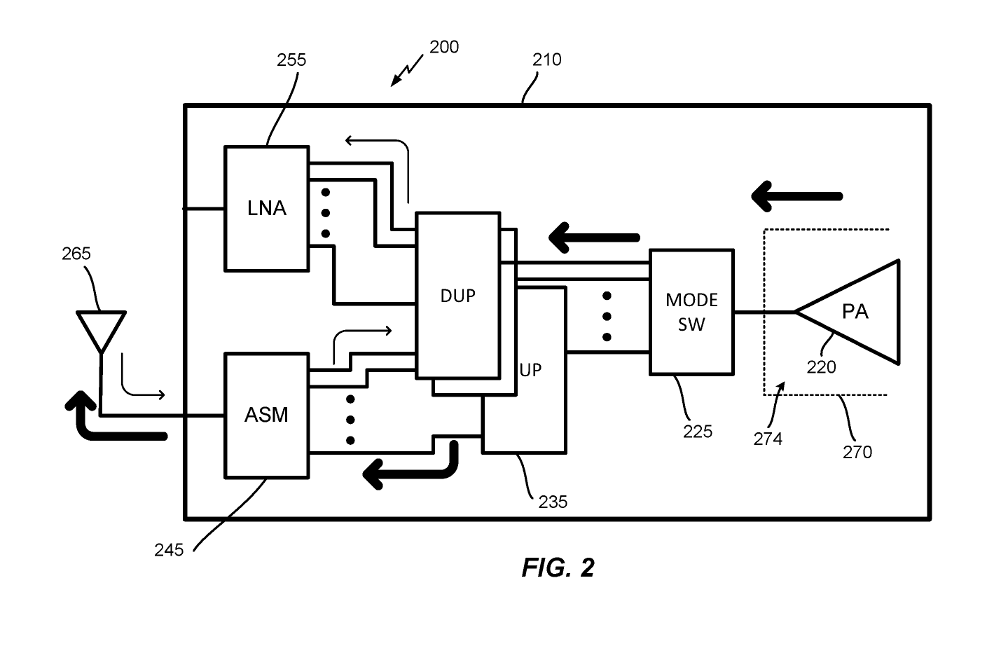

FIG. 2 illustrates an example of an RF module 200 according to a non-limiting aspect that addresses some or all issues of the conventional RF module 100. The RF module 200 is an example of a device package 200, or simply a package 200. The illustrated package 200 includes external shielding mechanisms. But in addition, the package 200 also includes internal shielding mechanisms as explained below.

The package 200 may comprise a plurality of devices contained within a conformal shield 210. For example, the plurality of devices may be contained within a volume defined by the conformal shield 210. The conformal shield 210 may be viewed as an example of means for external shielding since it is configured to shield the package 200 from external influences. The conformal shield 210 may also be referred as an “external” shield.

The plurality of devices may include an aggressor device 220 (e.g., a power amplifier (PA)), a plurality of duplexers (DUP) 235, a low noise amplifier (LNA) 235. The plurality of devices may also include a mode switch 225 and an antenna switch matrix (ASM) 245. The package 200 may be configured to process a plurality of frequency bands, and each DUP 235 may be configured to process a particular band. The mode switch 225 may be configured to route different bands of the outgoing signal from the aggressor device 220 to the proper DUP 235. Likewise, the ASM 245 may be configured to route different bands of the incoming signal received by the antenna 265 to the proper DUP 235. The ASM 245 may also be configured route the different bands of the outgoing signal to the antenna 265 for transmission. Each DUP 235 may be configured to isolate the outgoing and incoming signals from each other within its associated band to deliver the band of the incoming signal to the LNA 255. Thick arrows (indicating high power) show the path of the outgoing signals from the PA 220 to the antenna 165 through the mode switch 225, the DUP 235 and the ASM 245. Thin arrows (indicating low power) show the path of the incoming signals from the antenna 165 to the LNA 155 through the ASM 245 and the DUP 235.

The package 200 may also comprise an internal shield 270 (drawn as a dotted three-sided element) within the external shield 210. The internal shield 270, formed from a conductive material (e.g., copper), may be configured to mitigate the contamination of the incoming signal due to the aggressor device 220. Thus, the internal shield 270 may be viewed as an example of means for internal shielding. The internal shield 270 may define an interior shielding area 274. Note that the aggressor device 220, at least a part thereof, may be within the interior shielding area 274. While not shown in FIG. 2 specifically, the internal shield 270 can be assumed to be the grounded. It may also be assumed that there is at least one electrical path between the internal shield 270 and the ground independent of the external shield 210, i.e., there is at least one path to the ground other than through the external shield 210.

One operation (of which there can be several) of the internal shield 270 may be broadly explained as follows. The internal shield 270 may intercept at least some of the RF outgoing signal generated by the aggressor device 220 that would otherwise reach the external shield 210. The intercepted RF outgoing signal may induce current to flow in the internal shield 270. Since the internal shield 270 is the grounded other than through the external shield 210, the induced current flows to the ground through a path other than through the external shield. Thus, the current induced on the external shield 210 can be reduced, which in turn can reduce noise to the LNA 255, and thereby increase the sensitivity of the package 200 to the incoming signal.

Note that a path from the internal shield 270 to the ground through the external shield 210 is NOT excluded. Indeed, in some aspects, it may be preferable to ground the internal shield 270 through one or more paths that includes the external shield 210 and through one or more paths that do not. For example, when both types of paths are included, the internal shield 270 can provide an alternate conductive path to the ground for some of the current induced on the external shield 210. This can reduce the current noise on the LNA 255. This can be in addition to achieving noise reduction through RF signal interception described above.

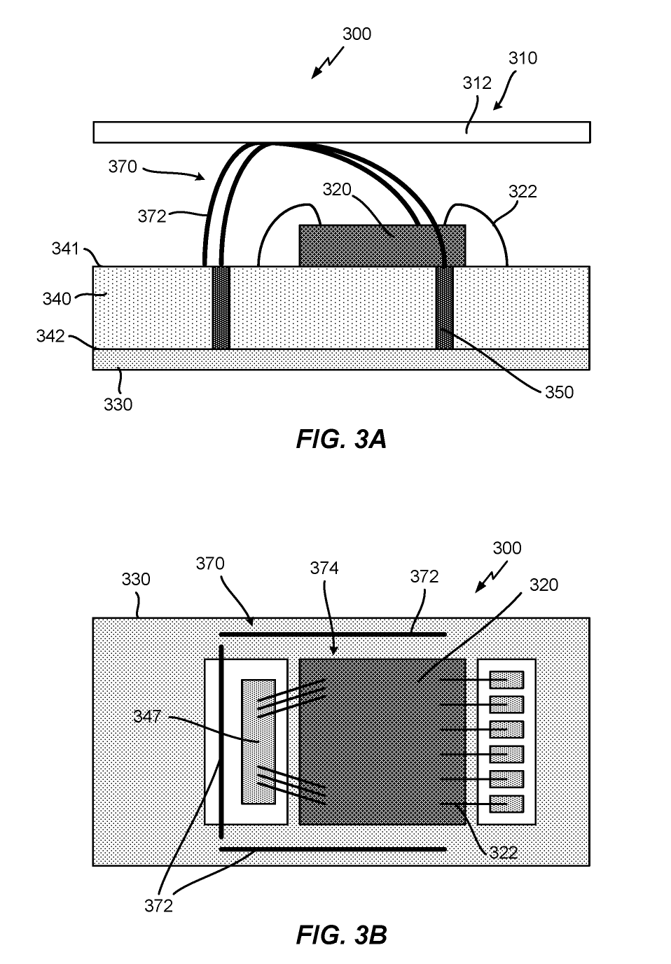

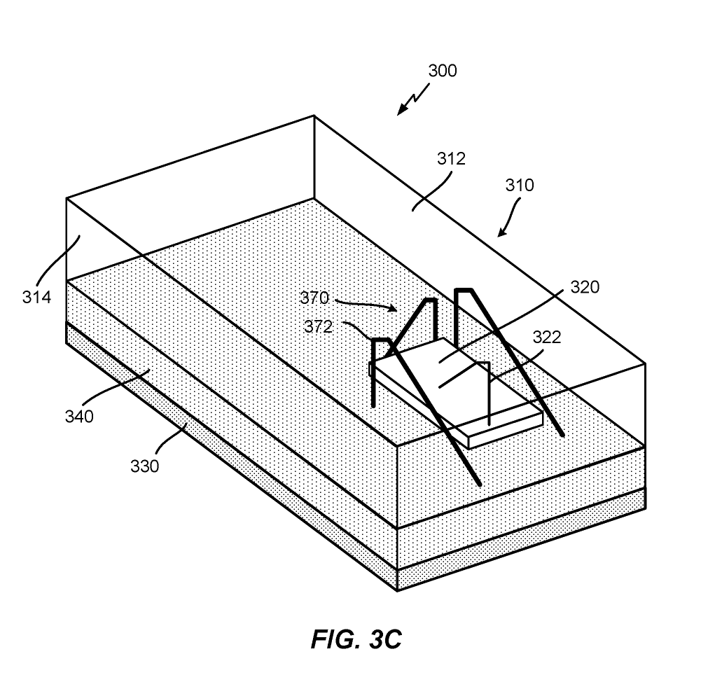

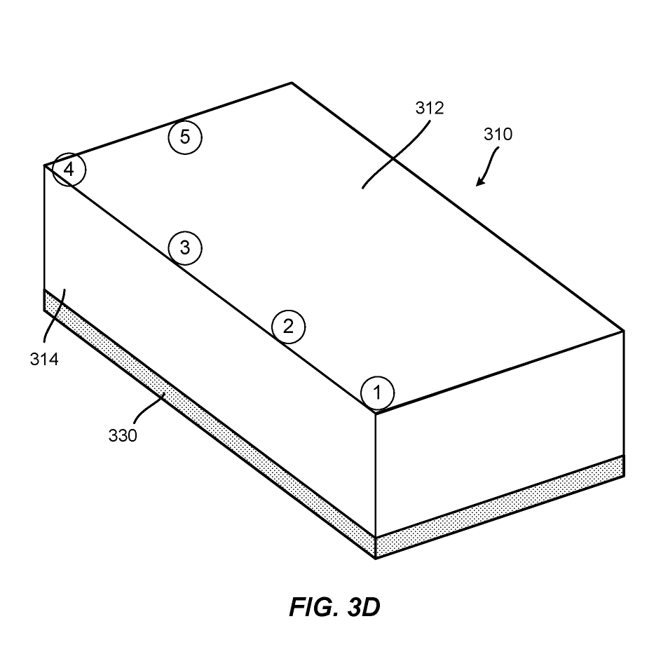

FIGS. 3A and 3B illustrate side and top views of an example package 300 according to a non-limiting aspect. In these figures, a portion of the package 300 in a vicinity of the aggressor device 320 (e.g., a power amplifier) is shown. The package 300 may comprise a substrate 340, e.g., a laminate substrate or a printed circuit board (PCB), with first surface 341 and an opposite second surface 342 and a ground plane 330 on the second surface 342 of the substrate 340.

The package 300 may also comprise an external shield 310 (e.g., a conformal field), which is another example of means for external shielding. The external shield 310 may be formed from conductive materials such as copper. In FIG. 3A, a top shield 312 (an example of means for top shielding) of the external shield 310 is shown. It should be noted that in addition to the top shield 312, the external shield 310 may also comprise one or more side shields 314 (examples of means for side shielding) as seen in FIGS. 3C and 3D. FIG. 3D in particular illustrates that one or more of the side shields 314 may be electrically coupled to the ground plane 330. For example, the side shields 314 may directly contact the ground plane 330. This means that the top shield 312 may be electrically coupled to the ground plane through one or more of the side shields 314.

But in FIG. 3A, the side shields 314 are omitted so that the elements of the package 300 within the external shield 310 may be illustrated. In FIG. 3B, the external shield 310 is completely omitted for the same reason. For reasons discussed further below, the substrate 340 is also omitted in FIG. 3B.

As seen in FIGS. 3A and 3B, the aggressor device 320 may be on the first surface 341 of the substrate 340. While not shown, it may be assumed that other devices of the plurality of devices illustrated in FIG. 2 are also on the first surface 341. The plurality of devices, including the aggressor device 320, may be within the external shield 310. For example, the devices may be within a volume defined by the external shield 310.

As an aside, it may be that the aggressor device 320 generates a significant amount of heat. The ground plane 330 may serve as a thermal ground to the plurality of devices including to the aggressor device 320, in addition to serving as an electrical ground.

The aggressor device 320 may comprise signal wire bonds 322 coupled to contact pads 347 on the substrate 340. FIG. 3B illustrates the signal wire bonds 322 being coupled to individual contact pads 347 on the right side of the aggressor device 320. These wire bonds 322 may carry individual input signals to the aggressor device 320. On the other hand, multiple signal wire bonds 322 may be coupled to a single contact pad 347 on the left side of the aggressor device 320. These wire bonds 322 together may carry the output signal of the aggressor device 320.

The package 300 may further include a wire bond (WB) cage 370 on the first surface 341 of the substrate 340 and within external shield 310. The WB cage 370 is an example of the internal shield 270 (see FIG. 2) and is another example of the means for internal shielding. As seen in FIG. 3B, the WB cage 370 may define an interior shielding area 374 within which at least a part of the aggressor device 320 is contained. In particular, the output of the aggressor device 320 may be within the interior shielding area 374. By surrounding the output of the aggressor device 320, the WB cage 370 may intercept a significant amount of the outgoing signal generated by the aggressor device 320. While interior shielding area 374 is illustrated as being defined by three-sides, this is not a limitation. The interior shielding area 374 can take on any shape.

The WB cage 370 may comprise a plurality of shielding wire bonds 372. In FIG. 3B, only three shielding wire bonds 372 are illustrated, each defining a side of the interior shielding area 374. However, this is done to minimize clutter, and should not be viewed as a limitation. The WB cage 370 may include any number of shielding wire bonds 372. Indeed, there can be any number of shielding wire bonds 372 per each side of the interior shielding area 374.

Recall that one feature of the internal shield 270 is that it may be electrically coupled to the ground through at least one path that does not include the external shield 210. Translating this feature to FIGS. 3A and 3B, the WB cage 370 may be grounded through a path that does not include the external shield 310. Again, this does NOT preclude one or more paths through the external shield 310. It is simply inclusive of aspects in which there is at least one alternate path to the ground from the WB cage 370.

In FIG. 3A, one or more alternate paths to the ground may be provided through a plurality of conductive vias 350, such as through-substrate-vias (TSVs). The plurality of conductive vias 350 may extend from the first surface 341 to the second surface 342 of the substrate 340. Also, the portions of the plurality of conductive vias 350 adjacent to the second surface 342 may be electrically coupled to the ground plane 330 (e.g., through direct contact). When one or both ends of one or more shielding wire bonds 372 are electrically coupled to the conductive vias 350 adjacent to the first surface 341 of the substrate 340 (e.g., through direct contact), then one or more alternate paths to the ground may be provided for the shielding wire bonds 372, and hence, may also be provided for the WB cage 370. In FIG. 3B, the substrate 340 is omitted to emphasize that the ends of the shielding wire bonds 372 may be coupled to the ground plane 330 without necessarily involving the external shield 310.

By providing the alternate paths to the ground, some amount of the outgoing signal from the aggressor device 320, which would otherwise inject noise on the external shield 310, the WB cage 370 can intercept and dissipate the noise to the ground through the alternate path. By surrounding, at least partially, the aggressor device 320 to be within the interior shielding area 374, the interception amount may be enhanced.

To further enhance the intercept capability, the height of the WB cage 370 may be above the aggressor device 320. For example, as seen in FIG. 3A, tops of one or more shielding wire bonds 372 may be higher than the aggressor device 320. Indeed, in a non-limiting aspect, the tops of one or more shielding wire bonds 372 may be in direct contact with the external shield 310, e.g., in contact with the top shield 312. More broadly, there may be a conductive path between the WB cage 370 and the external shield 310, e.g., the top portion of the WB cage 370 may be in direct contact with the top shield 312.

FIGS. 3C and 3D will be referred to in describing one benefit (of which there can be several) of having such conductive paths between the WB cage 370 and the external shield 310. FIG. 3C illustrates a perspective view of the example package 300 of FIGS. 3A and 3B. FIG. 3C illustrates the ground plane 330, the substrate 340, the aggressor device 320 and the WB cage 370. In this figure, the top and side shields 312, 314 of the external shield 310 are in an outline form to illustrate that the aggressor device 320 and the WB cage 370 are within the external shield 310.

FIG. 3D also illustrates a perspective view of the example package 300. But in this figure, the external shield 310 is drawn opaquely to more clearly present the top and side shields 312, 314. As seen, the external shield 310 may enclose the plurality of devices and the substrate 340. Also, one or more of the side shields 314 may directly contact the ground plane 330. Further, the top and side shields 312, 314 may be integrally formed, i.e., as a single piece.

As discussed, the outgoing signal from the aggressor device 320 can induce unwanted current flow on the surface of the external shield 310. In FIG. 3D, the circled numbers 1-5 indicate different locations of the top shield 312 where measurements of induced current may be made. 1 and 4 indicate near and far corner locations relative to the aggressor device 320, 2 and 3 indicate edge locations on a long side of the top shield 312, and 5 indicates an edge location on a a short side of the top shield 312 directly opposite the aggressor device 320.

Table I below show example measurements of induced current taken at the respective locations, with and without the WB cage 370. As seen in these measurements, the WB cage 370 can provide 13 dB or better improvements. Table I shows that the WB cage 370 can effectively suppress the coupling between the aggressor device 320 and the external shield 310.

TABLE I

| Location | WB Cage (dB) | No WB Cage (dB) | Improvement (dB) |
|---|---|---|---|
| 1 | −114.3 | −101.2 | −13.1 |
| 2 | −91.9 | −77.7 | −22.0 |
| 3 | −103.7 | −81.7 | −14.7 |
| 4 | −122.3 | −109.2 | −13.1 |
| 5 | −108.2 | −90.5 | −17.7 |

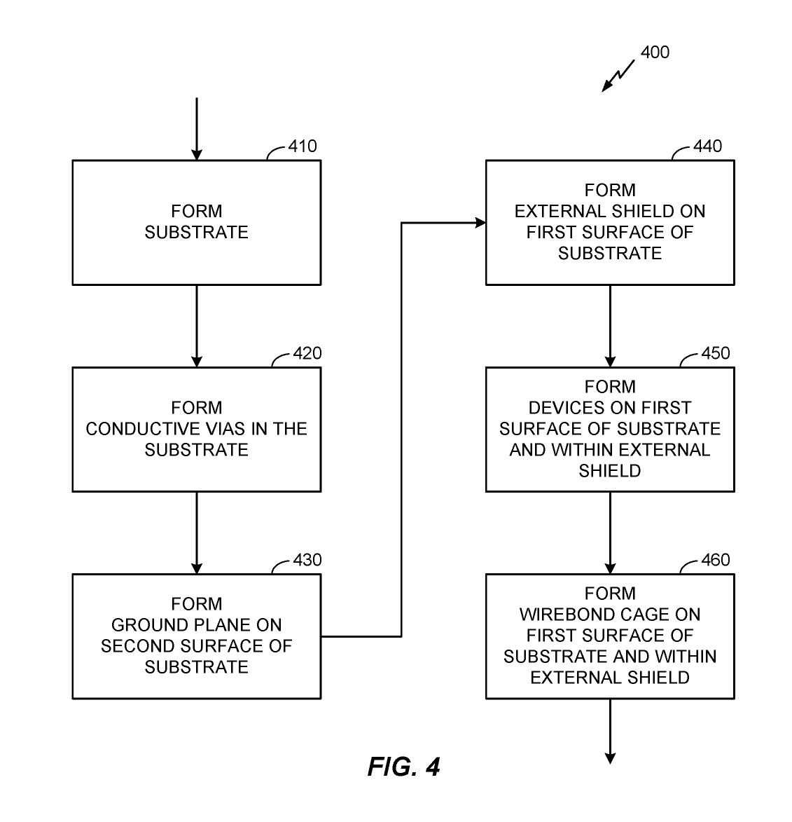

FIG. 4 illustrates a flow chart of an example method 400 of manufacturing a package, such as the package 300, according to a non-limiting aspect. It should be noted that it is not required to perform all illustrated blocks of FIG. 4, i.e., some blocks may be optional. Also, the numerical references to the blocks of FIG. 4 should not be taken as requiring that the blocks should be performed in a certain order.

In block 410, the substrate 340 with first and second surfaces 341, 342 may be formed. In block 420, a plurality of conductive vias 350, such as TSVs, maybe formed in the substrate 340. The plurality of conductive vias 350 may be formed to extend from first surface 341 to the second surface 342 of the substrate 340.

In block 430, the ground plane 330 may be formed on the second surface 342. In an aspect, the plurality of conductive vias 350 adjacent to the second surface 342 may be electrically coupled to the ground plane 330. For example, the plurality of conductive vias 350 may be in direct contact with the ground plane 330.

In block 440, the external shield 310, including the top and side shields 312, 314, may be formed. In an aspect, one or more of the side shields 314 may be formed so as to be electrically coupled to the ground plane 330 such that the top shield 312 is electrically coupled to the ground plane 330 through the side shields 314. For example, one or more of the side shields 314 may directly contact the ground plane 330. In an aspect, the external shield 310 may also enclose the substrate 340.

In block 450, a plurality of devices, including the aggressor device 320, may be formed on the first surface 341 of the substrate. The plurality of devices may be formed so as to be within the external shield 310. Thus, in an aspect, the plurality of devices may also be enclosed within the external shield 310.

In block 460, the WB cage 370 may be formed on the first surface 341 of the substrate 340, and within the external shield 310. The WB cage 370 may be formed so as to define the interior shielding area 374 within which at least a part of the aggressor device 320 is contained. For example, the output of the aggressor device 320 may be within the interior shielding area 374. The WB cage 370 may also be formed so that its height is above the aggressor device 320. The WB cage 370 may be electrically coupled the to the ground plane 330 in which there is at least one path from the WB cage 370 to the ground plane 330 other than through the external shield 310.

In an aspect, the WB cage 370 may comprise a plurality of shielding wire bonds 372 on the first surface 341. In this instance, electrically coupling the WB cage 370 to the ground plane 330 may comprise, for one or more shielding wire bonds 372 of the WB cage 370, electrically coupling one or both ends of the shielding wire bonds 372 to the ground plane 330 through a path that does not include the external shield 310. For example, one or both ends of the shielding wire bonds 372 may be coupled to the plurality of conductive vias 350 adjacent to the first surface 341. The WB cage 370 may be formed such that its top portion is in contact with the top shield 312 of the external shield 310. For example, top portions of one or more shielding wire bonds 372 may contact the top shield 312.

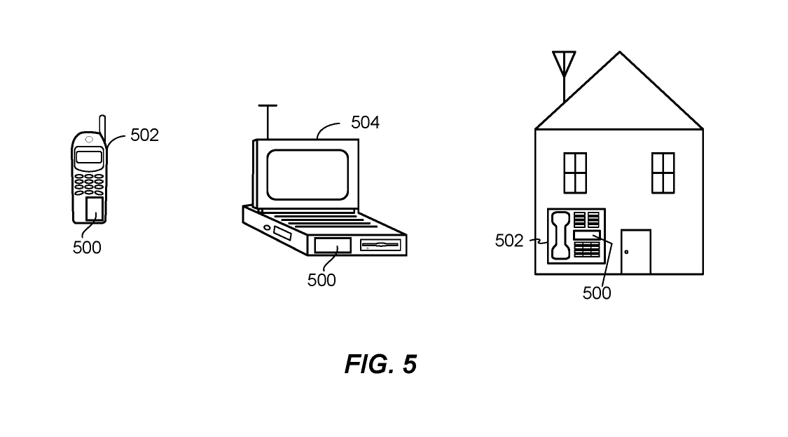

FIG. 5 illustrates various electronic devices that may be integrated with any of the aforementioned package 200, 300 illustrated as package 500 in the figure. For example, a mobile phone device 502, a laptop computer device 504, and a fixed location terminal device 506 may include a package 500 as described herein. The package 500 may be, for example, any of the integrated circuits, dies, integrated devices, integrated device packages, integrated circuit devices, device packages, integrated circuit (IC) packages, package-on-package devices described herein. The devices 502, 504, 506 illustrated in FIG. 8 are merely exemplary. Other electronic devices may also feature the package 500 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices, servers, routers, electronic devices implemented in automotive vehicles (e.g., autonomous vehicles), or any other device that stores or retrieves data or computer instructions, or any combination thereof.

Those of skill in the art will appreciate that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

Further, those of skill in the art will appreciate that the various illustrative logical blocks, modules, circuits, and algorithms described in connection with the examples disclosed herein may be implemented as electronic hardware, computer software, or combinations of both. To clearly illustrate this interchangeability of hardware and software, various illustrative components, blocks, modules, circuits, and methods have been described above generally in terms of their functionality. Whether such functionality is implemented as hardware or software depends upon the particular application and design constraints imposed on the overall system. Skilled artisans may implement the described functionality in varying ways for each particular application, but such implementation decisions should not be interpreted as causing a departure from the scope of the present disclosure.

The methods, sequences and/or algorithms described in connection with the examples disclosed herein may be embodied directly in hardware, in a software module executed by a processor, or in a combination of the two. A software module may reside in RAM memory, flash memory, ROM memory, EPROM memory, EEPROM memory, registers, hard disk, a removable disk, a CD-ROM, or any other form of storage medium known in the art. An exemplary storage medium is coupled to the processor such that the processor can read information from, and write information to, the storage medium. In the alternative, the storage medium may be integral to the processor.

Accordingly, an aspect can include a computer readable media embodying a method of forming a semiconductor device. Accordingly, the scope of the disclosed subject matter is not limited to illustrated examples and any means for performing the functionality described herein are included.

While the foregoing disclosure shows illustrative examples, it should be noted that various changes and modifications could be made herein without departing from the scope of the disclosed subject matter as defined by the appended claims. The functions, processes and/or actions of the method claims in accordance with the examples described herein need not be performed in any particular order. Furthermore, although elements of the disclosed subject matter may be described or claimed in the singular, the plural is contemplated unless limitation to the singular is explicitly stated.

1. A package, comprising:
a substrate with first and second surfaces;
a ground plane on the second surface of the substrate;
an external shield on the first surface of the substrate, the external shield comprising one or more side shields and a top shield, the side shields electrically coupled to the ground plane such that the top shield is electrically coupled to the ground plane through the side shields;
a plurality of devices on the first surface of the substrate and within the external shield, the plurality of devices including an aggressor device; and
a wire bond (WB) cage on the first surface of the substrate and within external shield, the WB cage defining an interior shielding area within which at least a part of the aggressor device is contained, and a height of the WB cage being above the aggressor device,
wherein the WB cage is electrically coupled to the ground plane in which there is at least one path from the WB cage to the ground plane other than through the external shield.

2. The package of claim 1,
wherein the WB cage comprises a plurality of shielding wire bonds on the first surface of the substrate, and
wherein for each shielding wire bond of the WB cage, one or both ends of that shielding wire bond are electrically coupled to the ground plane through a path that does not include the side shields.

3. The package of claim 1, wherein a top portion of the WB cage is in contact with the top shield of the external shield.

4. The package of claim 1, wherein an output of the aggressor device is within the interior shielding area of the WB cage.

5. The package of claim 1, further comprising a plurality of conductive vias extending from the first surface to the second surface of the substrate and electrically coupled to the ground plane adjacent to the second surface of the substrate,
wherein the WB cage is electrically coupled to the plurality of conductive vias adjacent to the first surface of the substrate.

6. The package of claim 1, wherein at least one side shield of the external shield directly contacts the ground plane.

7. The package of claim 1, wherein the external shield encloses the plurality of devices and the substrate.

8. The package of claim 1, wherein the side shields and the top shield of the external shield are integrally formed.

9. The package of claim 1, wherein the package is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle.

10. A method of manufacturing a package, the method comprising:
forming a substrate with first and second surfaces;
forming a ground plane on the second surface of the substrate;
forming an external shield on the first surface of the substrate, the external shield comprising one or more side shields and a top shield, the side shields electrically coupled to the ground plane such that the top shield is electrically coupled to the ground plane through the side shields;
forming a plurality of devices on the first surface of the substrate and within the external shield, the plurality of devices including an aggressor device; and
forming a wire bond (WB) cage on the first surface of the substrate and within external shield such that the WB cage defines an interior shielding area within which at least a part of the aggressor device is contained, and such that a height of the WB cage is above the aggressor device,
wherein forming the WB cage comprises electrically coupling the WB cage to the ground plane in which there is at least one path from the WB cage to the ground plane other than through the external shield.

11. The method of claim 10,
wherein the WB cage comprises a plurality of shielding wire bonds on the first surface of the substrate, and
wherein electrically coupling the WB cage to the ground plane comprises, for each shielding wire bond of the WB cage, electrically coupling one or both ends of that shielding wire bond to the ground plane through a path that does not include the side shields.

12. The method of claim 10, wherein forming the WB cage comprises forming the WB cage such that a top portion of the WB cage is in contact with the top shield of the external shield.

13. The method of claim 10, wherein forming the WB cage comprises forming WB cage such that an output of the aggressor device is within the interior shielding area of the WB cage.

14. The method of claim 10, further comprising forming a plurality of conductive vias extending from the first surface to the second surface of the substrate and electrically coupled to the ground plane adjacent to the second surface of the substrate,
wherein forming the WB cage comprises electrically coupling the WB cage to the plurality of conductive vias adjacent to the first surface of the substrate.

15. The method of claim 10, wherein forming the external shield comprises forming at least one side shield of the external shield to directly contact the ground plane.

16. The method of claim 10, wherein forming the external shield comprises forming the external shield so as to enclose the plurality of devices and the substrate.

17. A package, comprising:
a substrate with first and second surfaces;
a ground plane on the second surface of the substrate;
means for external shielding on the first surface of the substrate, the means for external shielding comprising means for side shielding and means for top shielding, the means for side shielding electrically coupled to the ground plane such that the means for top shielding is electrically coupled to the ground plane through the means for side shielding;
a plurality of devices on the first surface of the substrate and within the means for external shielding, the plurality of devices including an aggressor device; and
means for internal shielding on the first surface of the substrate and within the means for external shielding, the means for internal shielding defining an interior shielding area within which at least a part of the aggressor device is contained, and a height of the means for internal shielding being above the aggressor device,
wherein the means for internal shielding is electrically coupled to the ground plane in which there is at least one path from the means for internal shielding to the ground plane other than through the means for external shielding.

18. The package of claim 17, wherein a top portion of the means for internal shielding is in contact with the means for top shielding.

19. The package of claim 1, wherein an output of the aggressor device is within the interior shielding area of the means for internal shielding.

20. The package of claim 1, further comprising a plurality of conductive vias extending from the first surface to the second surface of the substrate and electrically coupled to the ground plane adjacent to the second surface of the substrate,
wherein the means for internal shielding is electrically coupled to the plurality of conductive vias adjacent to the first surface of the substrate.
